(19) United States
(12) Patent Application Publication
(10) Pub. No.: US 2026/0159953 A1
(43) Pub. Date: Jun. 11, 2026

(54) PROCESS, COMPONENT, AND SYSTEM WITH AMORPHOUS SILICON-CONTAINING COATING EXPOSED TO A TEMPERATURE OF GREATER THAN 600 DEGREES CELSIUS

(71) Applicant: SILCOTEK CORP., Bellefonte, PA (US)

(72) Inventors: Ashley BARLETT, Tyrone, PA (US); Min YUAN, State College, PA (US); Jesse BISCHOF, Bellefonte, PA (US); Geoffrey K. WHITE, State College, PA (US); Lucas D. PATTERSON, Altoona, PA (US); Gary A. BARONE, State College, PA (US)

(21) Appl. No.: 18/706,858

(22) PCT Filed: Oct. 19, 2022
(86) PCT No.: PCT/US2022/047086

§ 371 Date: May 2, 2024

Related U.S. Application Data
(60) Provisional application No. 63/275,128, filed on Nov. 3, 2021.

(51) Int. Cl. C23C 16/56; C04B 41/00; C04B 41/50; C04B 41/89; C23C 16/24; C23C 16/32

(52) U.S. Cl. CPC C23C 16/56; C04B 41/0072; C04B 41/5059; C04B 41/5096; C04B 41/89; C23C 16/24; C23C 16/325; C04B 2235/3826; C04B 2235/428

(57) ABSTRACT

Processes, components, and systems including such components are disclosed. The process includes providing a component having a substrate and an amorphous silicon-containing coating, and exposing the amorphous silicon-containing coating to a temperature greater than 600 degrees Celsius. The amorphous silicon-containing coating does not crystallize. The components include the substrate and the amorphous silicon-containing coating, with the coating having been exposed to the temperature greater than 600 degrees Celsius and the amorphous silicon-containing coating not crystallizing. The systems include the component.

### PRIORITY

The present application claims priority and benefit of PCT Patent Application PCT/US2022/047086, filed Oct. 19, 2022, entitled “PROCESS, COMPONENT, AND SYSTEM WITH AMORPHOUS SILICON-CONTAINING COATING EXPOSED TO A TEMPERATURE OF GREATER THAN 600 DEGREES CELSIUS,” claiming priority to U.S. Provisional Patent Application No. 63/275,128 , filed Nov. 3, 2021, the entirety of each is incorporated by reference.

### FIELD OF THE INVENTION

The present invention is directed to processes, components, and systems. More particularly, the present invention is directed to such processes and parts where silicon crystallization occurs at a temperature above 600 degrees Celsius.

### BACKGROUND OF THE INVENTION

Hydrogenated amorphous silicon is known to crystalize at around 700 degrees Celsius, depending upon the duration of exposure, pressure conditions, and other conditions. Amorphous silicon coating crystalizes at between 550 degrees Celsius and 600 degrees Celsius on stainless steel, for example, when coated according to U.S. Pat. No. 6,511,760 , entitled “METHOD OF PASSIVATING A GAS VESSEL OR COMPONENT OF A GAS TRANSFER SYSTEM USING A SILICON OVERLAY COATING.” Such amorphous silicon coatings are also known to crystalize at less than 450 degrees Celsius on aluminum.

Processes, components, and systems including such components that shows one or more improvements in comparison to the prior art would be desirable in the art.

### BRIEF DESCRIPTION OF THE INVENTION

In an embodiment, a process includes providing a component having a substrate and an amorphous silicon-containing coating, and exposing the amorphous silicon-containing coating to a temperature greater than 600 degrees Celsius. The amorphous silicon-containing coating does not crystallize.

In another embodiment, a component includes a substrate and an amorphous silicon-containing coating. The amorphous silicon-containing coating has been exposed to a temperature greater than 600 degrees Celsius and wherein the amorphous silicon-containing coating did not crystallize.

In another embodiment, a system includes a component. The component includes a substrate and an amorphous silicon-containing coating. The amorphous silicon-containing coating has been exposed to a temperature greater than 600 degrees Celsius and wherein the amorphous silicon-containing coating did not crystallize.

Other features and advantages of the present invention will be apparent from the following more detailed description, taken in conjunction with the accompanying drawings which illustrate, by way of example, the principles of the invention.

### BRIEF DESCRIPTION OF THE DRAWINGS

FIG. 1 is a schematic perspective view of a coated article, according to an embodiment of the disclosure.

Wherever possible, the same reference numbers will be used throughout the drawings to represent the same parts.

### DETAILED DESCRIPTION OF THE INVENTION

Provided are processes, components, and systems benefiting from increased silicon crystallization temperatures. Embodiments of the present disclosure, for example, in comparison to concepts failing to include one or more of the features disclosed herein, permit effectively instantaneous silicon crystallization to occur at increased temperatures, provide an oxidation barrier, prevent mismatches of coefficients of thermal expansion (and, therefore, reducing or eliminating delamination or other material failures due to thermal shocks/quenches), reduce or eliminate catalytic attack of and/or oxidative diffusion to a metal substrate (for example, by blocking pathways to exposed metal that is not blocked by crystalline silicon), reduce or eliminate chromium leaching from a metal substrate, reduce mass loss (for example, having less than 10 mils per year loss, less than 1 mil per year loss, less than 0.5 mils per year loss, or combinations thereof at increased temperatures, based upon 5%—by volume NaCl over a 7-day exposure period), or permit a combination thereof.

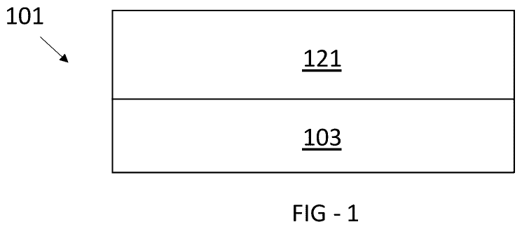

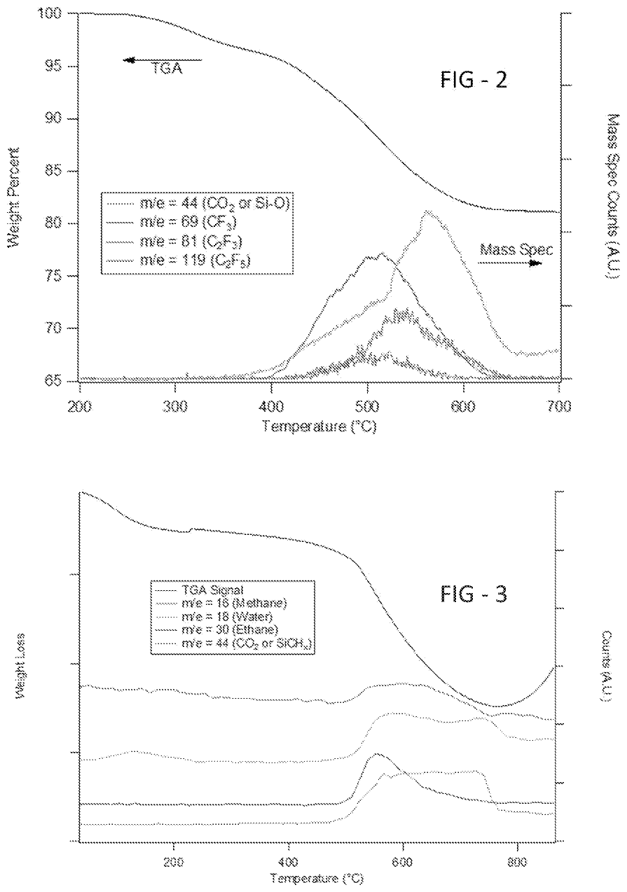

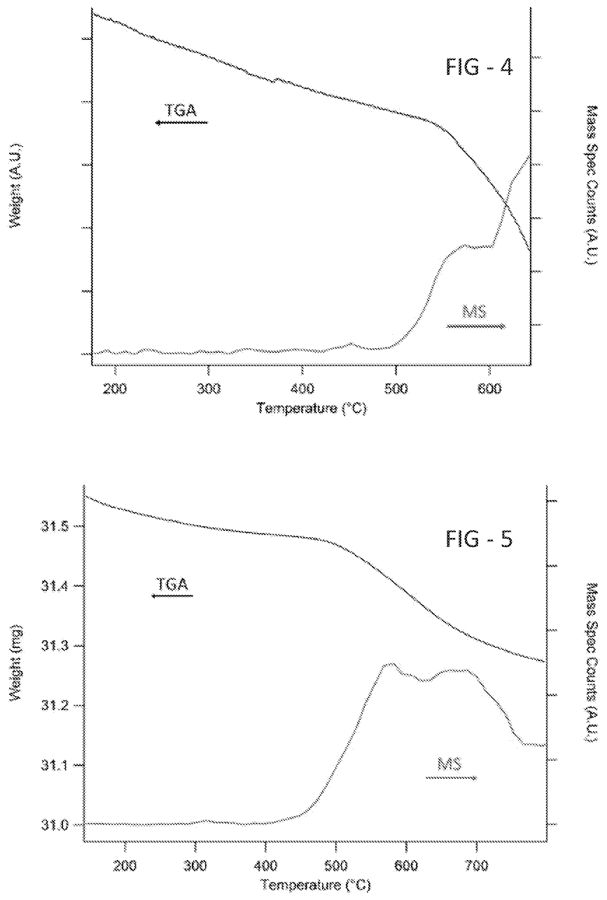

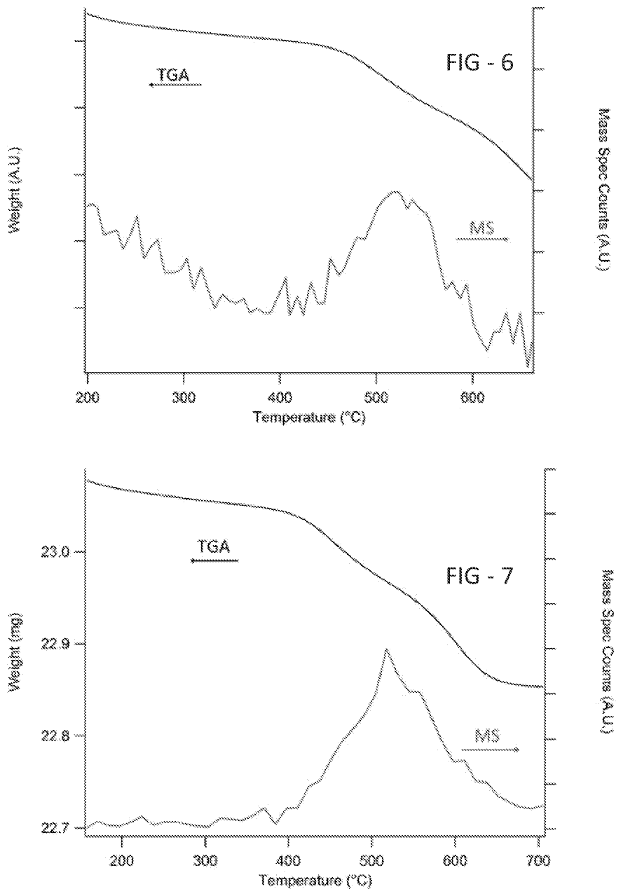

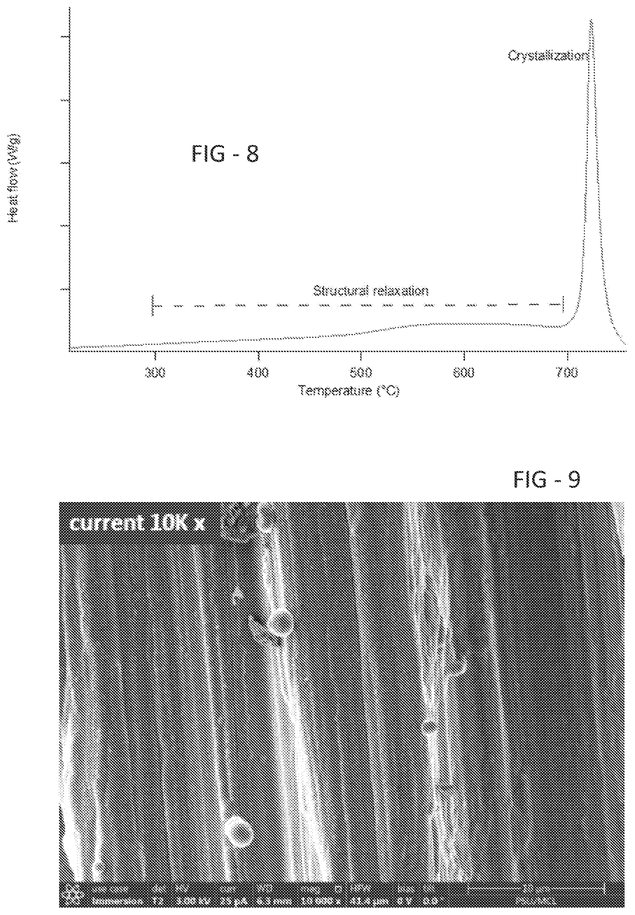

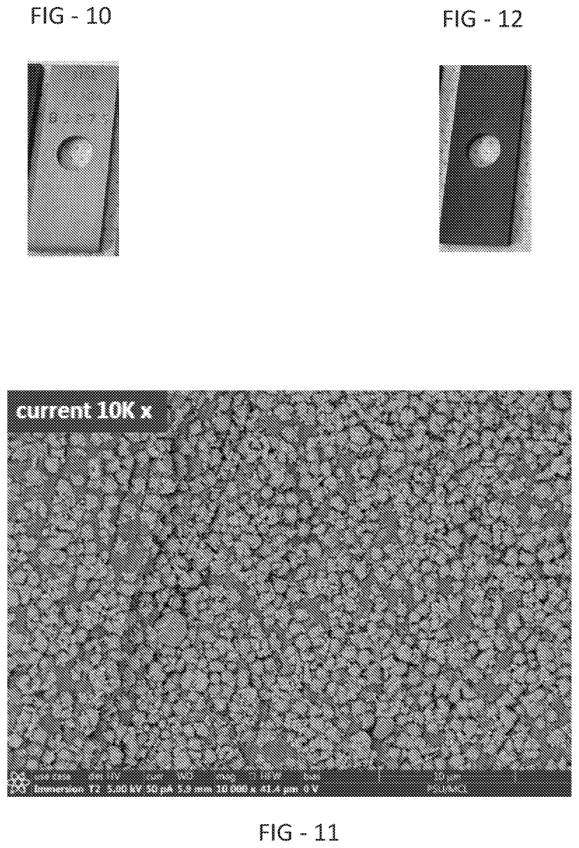

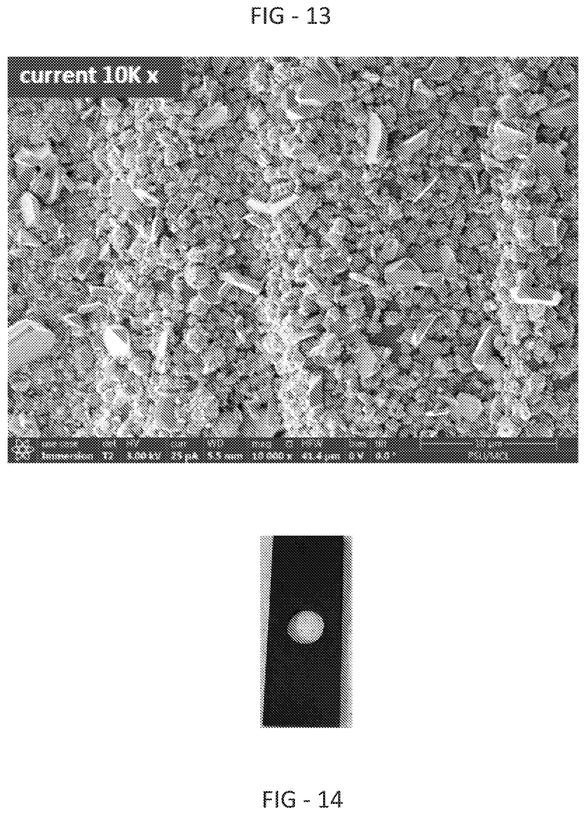

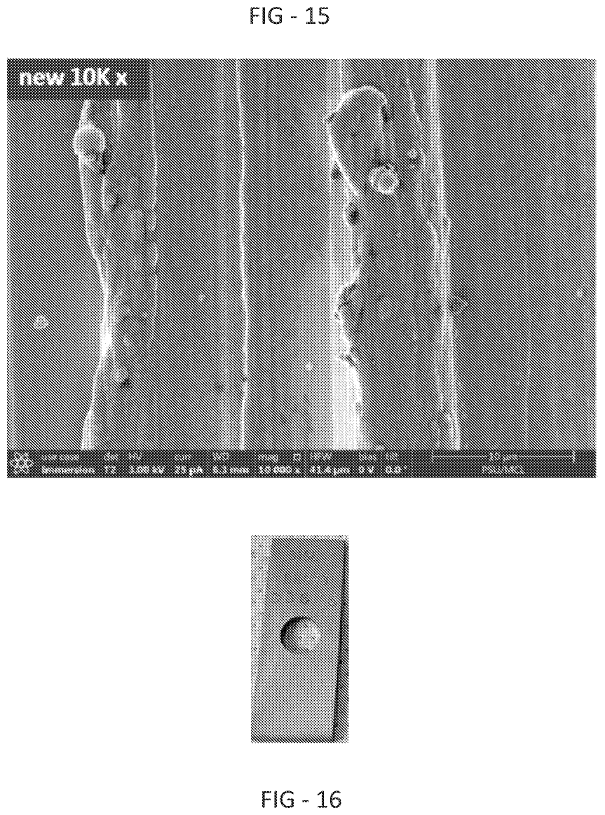

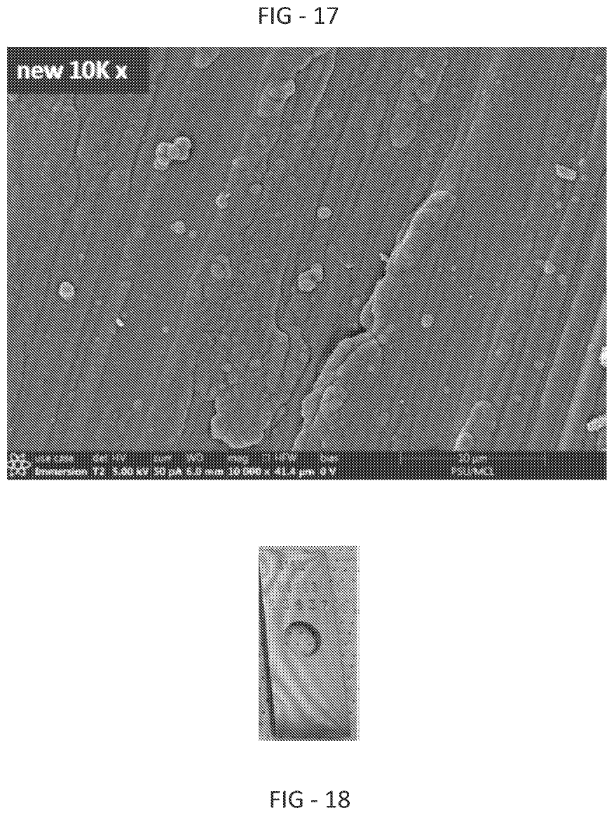

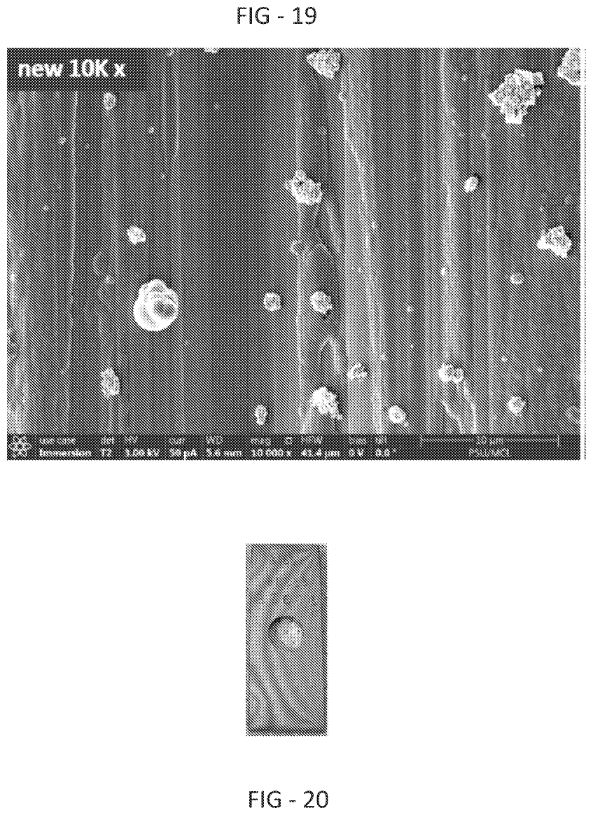

Referring to FIG. 1, according to an embodiment, a component 101 is coated according to a process consistent with the disclosure of Patent Cooperation Treaty Patent Application PCT/US2019/063513, titled “FLUID CONTACT PROCESS, COATED ARTICLE, AND COATING PROCESS,” filed November, 27, 2019, which is incorporated by reference in its entirety. The component 101 has a substrate 103 and coating 121.

The coating 121 is produced on all exposed surfaces. As used herein, the term “exposed,” with regard to “exposed surfaces,” refers to any surface that is in contact with gas during the process, and the term is not limited to line-of-sight surfaces or surfaces proximal to line-of-sight directions as are seen in flow-through chemical vapor deposition processes that do not have an enclosed vessel. As will be appreciated by those skilled in the art, the coated article 101 is capable of being incorporated into a larger component or system (not shown).

The coating 121 is produced, for example, thereby providing features and properties unique to being produced through the coating process, according to the disclosure, which is a static process using the enclosed vessel contrasted to flowable chemical vapor deposition that has concurrent flow of a precursor into and out of a chamber. As used herein, the phrase “thermal chemical vapor deposition” refers to a reaction and/or decomposition of one or more gases, for example, in a starved reactor configuration, and is distinguishable from plasma-assisted chemical vapor deposition, radical-initiated chemical vapor deposition, catalyst-assisted chemical vapor deposition, sputtering, atomic layer deposition (which is limited to a monolayer molecular deposition per cycle in contrast being capable of more than one layer of molecular deposition), and/or epitaxial growth (for example, growth at greater than 700° C.). In one embodiment, the coating 121 is on the component 101 on regions that are unable to be coated through line-of-sight techniques.

The coating 121 is formed by one or more of the following fluids, for example, decomposed sequentially, concurrently, or alone, before, during, after, or in the absence of oxidation and inert gas purge: silane, silane and ethylene, silane and an oxidizer, dimethylsilane, dimethylsilane and an oxidizer, trimethylsilane, trimethylsilane and an oxidizer, dialkylsilyl dihydride, alkylsilyl trihydride, non-pyrophoric species (for example, dialkylsilyl dihydride and/or alkylsilyl trihydride), thermally-reacted material (for example, carbosilane and/or carboxysilane, such as, amorphous carbosilane and/or amorphous carboxysilane), species capable of a recombination of carbosilyl (disilyl or trisilyl fragments), methyltrimethoxysilane, methyltriethoxysilane, dimethyldimethoxysilane, dimethyldiethoxysilane, trimethylmethoxysilane, trimethylethoxysilane, ammonia, hydrazine, trisilylamine, Bis(tertiary-butylamino)silane, 1,2-bis(dimethylamino)tetramethyldisilane, dichlorosilane, hexachlorodisilane), organofluorotrialkoxysilane, organofluorosilylhydride, organofluoro silyl, fluorinated alkoxysilane, fluoroalkylsilane, fluorosilane, tridecafluoro 1,1,2,2-tetrahydrooctylsilane, (tridecafluoro-1,1,2,2-tetrahydrooctyl) triethoxysilane, triethoxy (3,3,4,4,5,5,6,6,7,7,8,8,8-tridecafluoro-1-octyl) silane, (perfluorohexylethyl) triethoxysilane, silane (3,3,4,4,5,5,6,6,7,7,8,8,9,9,10,10,10-heptadecafluorodecyl) trimethoxy-, or a combination thereof.

Suitable thicknesses of the coating 121 include, but are not limited to, between 50 nanometers and 10,000 nanometers, between 50 nanometers and 1,000 nanometers, between 100 nanometers and 800 nanometers, between 200 nanometers and 600 nanometers, between 200 nanometers and 10,000 nanometers, between 500 nanometers and 3,000 nanometers, between 500 nanometers and 2,000 nanometers, between 500 nanometers and 1,000 nanometers, between 1,000 nanometers and 2,000 nanometers, between 1,000 nanometers and 1,500 nanometers, between 1,500 nanometers and 2,000 nanometers, 800 nanometers, 1,200 nanometers, 1,600 nanometers, 1,900 nanometers, or any suitable combination, sub-combination, range, or sub-range therein. More particularly, in one embodiment, the thickness of the coating 121 is between 50 nm and 900 nm, between 100 m and 800 nm, between 200 nm and 400 nm, between 300 nm and 600 nm, 50 nm, 100 nm, 150 nm, 200 nm, 250 nm, 300 nm, 350 nm, 400 nm, 450 nm, 500 nm, 550 nm, 600 nm, 650 nm, 700 nm, 750 nm, 800 nm, 850 nm, 900 nm, or any suitable combination, sub-combination, range, or sub-range therein.

Embodiments of the present application include processes of using the component 101 at increased temperatures, systems incorporating the component 101 at the increased temperatures, and the component 101 during and after exposure to the increased temperatures that otherwise crystallize amorphous silicon. For example, embodiments include the increased temperatures being greater than 600 degrees Celsius, greater than 650 degrees Celsius, greater than 700 degrees Celsius, 720 degrees Celsius, 750 degrees Celsius, greater than 790 degrees Celsius, between the 600 degrees Celsius and 800 degrees Celsius, between the 600 degrees Celsius and 700 degrees Celsius, between 750 degrees Celsius and 800 degrees Celsius, between 700 degrees Celsius and 800 degrees Celsius, between the 750 degrees Celsius and 800 degrees Celsius, or any suitable combination, sub-combination, range, or sub-range therein. In further embodiments, the increased temperature is in an oxidative environment (for example, through air, oxygen, or water) or an inert environment (for example, through argon, helium, or nitrogen).

In one embodiment, the process of using the component 101 includes exposing the coating 121, during or after exposure to the increased temperatures, to chemical species. The chemical species are generally fluids, for example, gases and liquids. In some embodiments, the chemical species further include particulate (such as, soot, carbonaceous material, coke, etc.). In one embodiment, the chemical species are selected from the group consisting of NOx, SOx, NH3, H2S, mercaptans, hydrocarbons, HCl, NaCl (for example, 5%, by volume over 7 days), volatile organic compounds, Mercury (whether oxidized or elemental), polycyclic aromatic hydrocarbons, a variety of other species, naphtha, petroleum naptha, napthenes (cylcoalkanes), fuel oils, natural gas, hydrogen, high boiling point hydrocarbons, high molecular weight hydrocarbons, heavy gas oils, ethanolamines (sulfur scrubbing material), vacuum gas oil, bunker fuels, petroleum distillates (for example, that which is cracked or distilled), heavy crudes, distillate bottoms, jet fuels, diesel fuels, gasoline, kerosene, saturated hydrocarbons, straight chain alkane (for example, parrafins), olefins/alkenes (for example, straight and/or branched), isobutane, ethylene, propylene, ethane, moisture (for example, H₂O as steam or low concentration contaminate in hydrocarbon stream), HF, H₂SO₄, or combinations thereof.

In one embodiment, the component 101 is used within catalytic converter systems where loss of performance is traditionally caused by fouling and particulate sticking to reaction sites of catalyst particles, bed and structures. The component 101 reduces or eliminates carbon fouling caused by hydrocarbons within fuels, for example, by serving the coating 121 serving as a barrier coating with low adhesive properties that allows material to flow through without sticking.

In one embodiment, the component 101 is used within a stationary power generation system to control corrosion and/or fuel coking/fouling, thereby prolonging usable life, providing better fuel economy, enabling extended maintenance cycles, and increasing durability. The component 101 is positioned within hot areas of fuel transfer equipment (for example, pipes, injectors, and/or burners) and reduces or eliminates traditional fouling and/or blocking of hot fuel transfer lines near an engine or during soaking conditions when fuel is not circulating, for example, by the coating 121 serving as a barrier coating with low adhesive properties that allows material to flow through without sticking.

In one embodiment, the component 101 is used within a high temperature refining and/or petrochemical system, thereby prolonging usable life, enabling extended maintenance cycles, and increasing durability. The component 101 is positioned within a distillation system that is otherwise subject to fouling of distillation trays (thereby reducing efficiency) and/or subject to corrosion of distillation trays (thereby reducing usable life). The coating 121 resist the fouling build-up of hydrocarbons and other organic materials and/or provides a corrosion resistant barrier increasing usable life.

Additionally or alternatively, in one embodiment, the component 101 is positioned within a steam reformer that is otherwise subject to catalyst poisoning (for example, from sulfur-containing compounds) and/or fouling (for example, from carbon) in reformer tubes typically operating at temperatures above 750 degrees Celsius. The coating 121 assures proper testing of catalyst poisoning (for example, sulfur) in analytical and process analyzers to reduce or eliminate adsorptive losses and/or reduces build-up of fouling material (for example, carbon) by serving as a barrier coating that reduces or eliminates adherence of carbon.

Additionally or alternatively, in one embodiment, the component 101 is used within a HF process (for example Philips alkylation process) that is otherwise subject to decreased usable life due to HF attack and/or inadequate performance of analytical systems in monitoring feed stock levels of species (for example, sulfurs) due to corrosion. The coating 121 extends the usable life of equipment in contact with the HF and/or increases performance of the analytical systems by reducing or eliminating corrosion.

Additionally or alternatively, in one embodiment, the component 101 is used within a steam cracker that is otherwise subject to fouling of furnace tubes that operate in excess of 750 degrees Celsius. The coating 121 serves as a barrier coating, preventing the fouling of the furnace tubes.

Additionally or alternatively, in one embodiment, the component 101 is used within a pilot plant operation that is otherwise subject to wall-effect impact by contributing to a reaction due to metal contact. The coating 121 serves as a barrier coating that inhibits reactions with the reactor wall.

In one embodiment, the component 101 is used within a combustion engine and/or chamber (for example, spark or compression), thereby enhancing corrosion resistance, reducing or eliminating fuel coking/fouling, thereby prolonging usable life, increasing fuel economy, enabling longer maintenance cycles, and/or increasing durability. The component 101 is positioned in a region otherwise subject to fouling, plugging, and reduced flow, for example, due to relatively small holes and high pressures (for example, in injectors), losses of compression or scoring (for example, in pistons), build-up (for example, on a piston face), performance reductions (for example, from particulate build-up on fuel transfer lines in jet engines heated by engine proximity, soaked fuel transfer lines, intake valve, exhaust valves, turbo-charger housings, and/or more generally sensors, valves, passageways,), or combinations thereof. The coating 121 resist the fouling build-up of hydrocarbons and other organic materials and/or provides a corrosion resistant barrier increasing usable life.

Other suitable uses of the component 101 include, but are not limited to, exposure to the increased temperatures within or as pumps, portions of pumps (such as, pump vanes), tubular and/or piping elements, off-shore oil and gas systems (with or without exposure to saltwater), well pads, drilling components, compressive natural gas extraction, upstream and/or downstream flow paths, petrochemical refineries, hydrocarbon processing, process analyzers, dissolved gas analyzers, galvanic corrosive environments, mercuric corrosive environments, gas storage vessels, fittings, compression fittings, tubing, valves, quick-connects, sample cylinders, regulators and/or flow-controllers, injection ports, in-line filters, frits, rails, racks, drive-trains, rods, clamps, bolts, guiderails, wheel wells, lattices, filters, gas storage containers, loading platforms, or combinations thereof.

Processes specific to certain industries able to benefit from the component 101 include, but are not limited to, oil & gas, semiconductor manufacturing, semiconductor equipment (for example gas lines, bellows, heat shields, weldments, flanges, mesh, filters, rings, housing, chambers, and/or canisters), analytical instrumentation, life science and pharmaceutical manufacturing, refining, chemical processing, off-shore technologies, aerospace technologies, non-Earthly environments (for example, Venus, Mars, moons, and other celestial bodies), deep sea, volcanic and/or hydrothermal environments, polishing and cleaning industries, molding, particle physics, mining, metal production, hydrogen processing and extraction, nuclear energy production (fission and fusion), glass and ceramic manufacturing, transportation (especially in harsh environments), agriculture (especially when requiring high temperature processing), coatings manufacturing (for example, radiation-cured coatings, polymeric coating application and production, oligomeric coating application and production, and/or curing environments, such as, ovens, lamps, UV-lamps, electron beam chambers, etc.), specialty gas production, clean-air and carbon capture technology, analytical instrumentation, weapons/defense (especially missiles, drones, bombs, projectiles, etc.), reactors, boilers, catalyst production, submersibles, and combinations thereof.

The substrate 103 includes any suitable material(s) able to withstand temperatures of at least 600 degrees and, in some embodiments, higher temperatures consistent with the increased exposure temperatures without sacrificing operational usefulness and/or causing interlaminar failures. Suitable materials include, but are not limited to, ferrous-based alloys, non-ferrous-based alloys, nickel-based alloys, martensitic stainless steels, austenitic stainless steels, ceramic, glass, ceramic matrix composites, aluminum alloys (for example, having at least 50%, by weight aluminum), titanium alloys (for example, having at least 50%, by weight titanium), alloys or pure materials subject to oxidative attack, or combinations thereof. In various embodiments, the substrate 103 is a metallic material that is tempered or non-tempered, has grain structures that are equiaxed, directionally-solidified, and/or single crystal, has amorphous or crystalline structures, is a foil, fiber, a cladding, and/or a film.

In one embodiment, the metallic material has a first iron concentration and a first chromium concentration, the first iron concentration being greater than the first chromium concentration. For example, suitable values for the first iron concentration include, but are not limited to, by weight, greater than 50%, greater than 60%, greater than 66%, greater than 70%, between 66% and 74%, between 70% and 74%, or any suitable combination, sub-combination, range, or sub-range therein. Suitable values for the first chromium concentration include, but are not limited to, by weight, greater than 10.5%, greater than 14%, greater than 16%, greater than 18%, greater than 20%, between 14% and 17%, between 16% and 18%, between 18% and 20%, between 20% and 24%, or any suitable combination, sub-combination, range, or sub-range therein.

In one embodiment, the metallic material is or includes a composition, by weight, of up to 0.08% carbon, between 18% and 20% chromium, up to 2% manganese, between 8% and 10.5% nickel, up to 0.045% phosphorus, up to 0.03% sulfur, up to 1% silicon, and a balance of iron (for example, between 66% and 74% iron).

In one embodiment, the metallic material is or includes a composition, by weight, of up to 0.08% carbon, up to 2% manganese, up to 0.045% phosphorus, up to 0.03% sulfur, up to 0.75% silicon, between 16% and 18% chromium, between 10% and 14% nickel, between 2% and 3% molybdenum, up to 0.1% nitrogen, and a balance of iron.

In one embodiment, the metallic material is or includes a composition, by weight, of up to 0.03% carbon, up to 2% manganese, up to 0.045% phosphorus, up to 0.03% sulfur, up to 0.75% silicon, between 16% and 18% chromium, between 10% and 14% nickel, between 2% and 3% molybdenum, up to 0.1% nitrogen, and a balance of iron.

In one embodiment, the metallic material is or includes a composition, by weight, of between 14% and 17% chromium, between 6% and 10% iron, between 0.5% and 1.5% manganese, between 0.1% and 1% copper, between 0.1% and 1% silicon, between 0.01% and 0.2% carbon, between 0.001% and 0.2% sulfur, and a balance nickel (for example, 72%).

In one embodiment, the metallic material is or includes a composition, by weight, of between 20% and 24% chromium, between 1% and 5% iron, between 8% and 10% molybdenum, between 10% and 15% cobalt, between 0.1% and 1% manganese, between 0.1% and 1% copper, between 0.8% and 1.5% aluminum, between 0.1% and 1% titanium, between 0.1% and 1% silicon, between 0.01% and 0.2% carbon, between 0.001% and 0.2% sulfur, between 0.001% and 0.2% phosphorus, between 0.001% and 0.2% boron, and a balance nickel (for example, between 44.2% and 56%).

In one embodiment, the metallic material is or includes a composition, by weight, of between 20% and 23% chromium, between 4% and 6% iron, between 8% and 10% molybdenum, between 3% and 4.5% niobium, between 0.5% and 1.5% cobalt, between 0.1% and 1% manganese, between 0.1% and 1% aluminum, between 0.1% and 1% titanium, between 0.1% and 1% silicon, between 0.01% and 0.5% carbon, between 0.001% and 0.02% sulfur, between 0.001% and 0.02% phosphorus, and a balance nickel (for example, 58%).

In one embodiment, the metallic material is or includes a composition, by weight, of between 25% and 35% chromium, between 8% and 10% iron, between 0.2% and 0.5% manganese, between 0.005% and 0.02% copper, between 0.01% and 0.03% aluminum, between 0.3% and 0.4% silicon, between 0.005% and 0.03% carbon, between 0.001% and 0.005% sulfur, and a balance nickel (for example, 59.5%).

In one embodiment, the metallic material is or includes a composition, by weight, of between 17% and 21% chromium, between 2.8% and 3.3% iron, between 4.75% and 5.5% niobium, between 0.5% and 1.5% cobalt, between 0.1% and 0.5% manganese, between 0.2% and 0.8% copper, between 0.65% and 1.15% aluminum, between 0.2% and 0.4% titanium, between 0.3% and 0.4% silicon, between 0.01% and 1% carbon, between 0.001 and 0.02% sulfur, between 0.001 and 0.02% phosphorus, between 0.001 and 0.02% boron, and a balance nickel (for example, between 50% and 55%).

In one embodiment, the metallic material is or includes a composition, by weight, of between 2% and 3% cobalt, between 15% and 17% chromium, between 5% and 17% molybdenum, between 3% and 5% tungsten, between 4% and 6% iron, between 0.5% and 1% silicon, between 0.5% and 1.5% manganese, between 0.005 and 0.02% carbon, between 0.3% and 0.4% vanadium, and a balance nickel.

In one embodiment, the metallic material is or includes a composition, by weight, of up to 0.15% carbon, between 3.5% and 5.5% tungsten, between 4.5% and 7% iron, between 15.5% and 17.5% chromium, between 16% and 18% molybdenum, between 0.2% and 0.4% vanadium, up to 1% manganese, up to 1% sulfur, up to 1% silicon, up to 0.04% phosphorus, up to 0.03% sulfur, and a balance nickel.

In one embodiment, the metallic material is or includes a composition, by weight, of up to 2.5% cobalt, up to 22% chromium, up to 13% molybdenum, up to 3% tungsten, up to 3% iron, up to 0.08% silicon, up to 0.5% manganese, up to 0.01% carbon, up to 0.35% vanadium, and a balance nickel (for example, 56%).

In one embodiment, the metallic material is or includes a composition, by weight, of between 1% and 2% cobalt, between 20% and 22% chromium, between 8% and 10% molybdenum, between 0.1% and 1% tungsten, between 17% and 20% iron, between 0.1% and 1% silicon, between 0.1% and 1% manganese, between 0.05 and 0.2% carbon, and a balance nickel.

In one embodiment, the metallic material is or includes a composition, by weight, of between 0.01% and 0.05% boron, between 0.01% and 0.1% chromium, between 0.003% and 0.35% copper, between 0.005% and 0.03% gallium, between 0.006% and 0.8% iron, between 0.006% and 0.3% magnesium, between 0.02% and 1% silicon+iron, between 0.006% and 0.35% silicon, between 0.002% and 0.2% titanium, between 0.01% and 0.03% vanadium+titanium, between 0.005% and 0.05% vanadium, between 0.006% and 0.1% zinc, and a balance aluminum (for example, greater than 99%)

In one embodiment, the metallic material is or includes a composition, by weight, of between 0.05% and 0.4% chromium, between 0.03% and 0.9% copper, between 0.05% and 1% iron, between 0.05% and 1.5% magnesium, between 0.5% and 1.8% manganese, between 0.5% and 0.1% nickel, between 0.03% and 0.35% titanium, up to 0.5% vanadium, between 0.04% and 1.3% zinc, and a balance aluminum (for example, between 94.3% and 99.8%).

In one embodiment, the metallic material is or includes a composition, by weight, of between 0.0003% and 0.07% beryllium, between 0.02% and 2% bismuth, between 0.01% and 0.25% chromium, between 0.03% and 5% copper, between 0.09% and 5.4% iron, between 0.01% and 2% magnesium, between 0.03% and 1.5% manganese, between 0.15% and 2.2% nickel, between 0.6% and 21.5% silicon, between 0.005% and 0.2% titanium, between 0.05% and 10.7% zinc, and a balance aluminum (for example, between 70.7% to 98.7%).

In one embodiment, the metallic material is or includes a composition, by weight, of between 0.15% and 1.5% bismuth, between 0.003% and 0.06% boron, between 0.03% and 0.4% chromium, between 0.01% and 1.2% copper, between 0.12% and 0.5% chromium+manganese, between 0.04% and 1% iron, between 0.003% and 2% lead, between 0.2% and 3% magnesium, between 0.02% and 1.4% manganese, between 0.05% and 0.2% nickel, between 0.5% and 0.5% oxygen, between 0.2% and 1.8% silicon, up to 0.05% strontium, between 0.05% and 2% tin, between 0.01% and 0.25% titanium, between 0.05% and 0.3% vanadium, between 0.03% and 2.4% zinc, between 0.05% and 0.2% zirconium, between 0.150 and 0.2% zirconium+titanium, and a balance of aluminum (for example, between 91.7% and 99.6%).

In one embodiment, the metallic material is or includes a composition, by weight, of between 0.4% and 0.8% silicon, up to 0.7% iron, between 0.15% and 0.4% copper, up to 0.15% manganese, between 0.8% and 1.2% magnesium, between 0.04% and 0.35% chromium, up to 0.25% zinc, up to 0.15% titanium, optional incidental impurities (for example, at less than 0.05% each, totaling less than 0.15%), and a balance of aluminum (for example, between 95% and 98.6%).

In one embodiment, the metallic material is or includes a composition, by weight, of between 11% and 13% silicon, up to 0.6% impurities/residuals, and a balance of aluminum.

In one embodiment, the metallic material is or includes a composition, by weight, of between 0.7% and 1.1% magnesium, between 0.6% and 0.9% silicon, between 0.2% and 0.7% iron, between 0.1% and 0.4% copper, between 0.05% and 0.2% manganese, 0.02% and 0.1% zinc, 0.02% and 0.1% titanium, and a balance aluminum. In a further embodiment, the metallic material is Alloy 6061.

### EXAMPLES

In a first comparative example, a 0.02 mm thick foil stainless steel substrate is coated on a surface area of about 0.5 cm² . The coating has about 500 nm of thickness and a density of 2.25 g/cm³. The coating represents about 0.1% of the mass of the coated substrate. The coated substrate is exposed to temperatures up to 800 degrees Celsius, however, detectable mass loss is not available due to the relative difference in mass between the coating and the substrate.

In a second comparative example, a silica particle is coated. The coating has about 100 nm of thickness and a density of 2.25 g/cm³. The silica particle has a volume of 0.113 μm³ and the coating has a volume of 0.155 μm³ on the silica particle. The coating represents about 57.8% of the mass of the coated silica particle. The coating includes fluorine, silicon, oxygen, carbon, and hydrogen. The coated silica particle is exposed to thermal gravimetric analysis as shown in data. The thermal gravimetric analysis shows evolution of constituents from the coating and destruction of the coating by about 400 degrees Celsius.

In a third comparative example, a silica particle is coated. The coating has about 100 nm of thickness and a density of 2.25 g/cm³. The silica particle has a volume of 0.113 μm 3 and the coating has a volume of 0.155 μm³ on the silica particle. The coating represents about 57.8% of the mass of the coated silica particle. The coating includes silicon, oxygen, carbon, and hydrogen. The coated silica particle is exposed to thermal gravimetric analysis as shown in data. The thermal gravimetric analysis shows evolution of constituents from the coating and destruction of the coating by about 400 degrees Celsius.

In a fourth comparative example, a silica particle is coated. The coating has about 100 nm of thickness and a density of 2.25 g/cm³. The silica particle has a volume of 0.113 μm³ and the coating has a volume of 0.155 μm³ on the silica particle. The coating represents about 57.8% of the mass of the coated silica particle. The coating includes silicon, oxygen, carbon, and hydrogen. The coated silica particle is exposed to thermal gravimetric analysis in an inert environment as shown in data and an oxygen environment as shown in data. The thermal gravimetric analysis shows evolution and destruction of the coating by about 500 degrees Celsius in the inert environment and about 450 degrees Celsius in the oxygen environment.

In a fifth comparative example, a silica particle is coated. The coating has about 100 nm of thickness and a density of 2.25 g/cm³. The silica particle has a volume of 0.113 μm³ and the coating has a volume of 0.155 μm³ on the silica particle. The coating represents about 57.8% of the mass of the coated silica particle. The coating includes silicon, carbon, and hydrogen. The coated silica particle is exposed to thermal gravimetric analysis in an inert environment as shown in data and an oxygen environment as shown in data. The thermal gravimetric analysis shows evolution and destruction of the coating by about 430 degrees Celsius in the inert environment and 400 degrees Celsius in the oxygen environment.

In a sixth comparative example, a silica particle is coated with an amorphous silicon-containing coating. The coating has about 100 nm of thickness and a density of 2.25 g/cm³. The silica particle has a volume of 0.113 μm³ and the coating has a volume of 0.155 μm³ on the silica particle. The coating represents about 57.8% of the mass of the coated silica particle. The coating includes silicon and hydrogen. The coated silica particle is exposed to thermal gravimetric analysis as shown in data. The thermal gravimetric analysis shows crystallization of the coating initiating at about 700 degrees Celsius and concluding at 720 degrees Celsius. The same coating on a stainless steel substrate is also analyzed visually and through scanning electron microscopy after air-exposure at temperatures of 600 degrees Celsius as shown in FIGS. 9-10, at temperatures of 700 degrees Celsius as shown in FIGS. 11-12, and at temperatures of 800 degrees Celsius as shown in FIGS. 13-14. The coating is amorphous and generally transparent/translucent at 600 degrees Celsius and crystalline and blackish or black at the higher temperatures, specifically 700 degrees Celsius and 800 degrees Celsius.

In a seventh example, according to an embodiment of the disclosure, a coating includes carbon, silicon, and hydrogen. The coating on a stainless steel substrate is analyzed visually and through scanning electron microscopy after air-exposure at temperatures of 600 degrees Celsius as shown in FIGS. 15-16, at temperatures of 700 degrees Celsius as shown in FIGS. 17-18, and at temperatures of 800 degrees Celsius as shown in FIGS. 19-20. The coating is amorphous and generally transparent/translucent at 600 degrees Celsius, 700 degrees Celsius, and 800 degrees Celsius.

While the invention has been described with reference to one or more embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims. In addition, all numerical values identified in the detailed description shall be interpreted as though the precise and approximate values are both expressly identified.

1. A process, comprising:
providing a component having a substrate and an amorphous silicon-containing coating; and
exposing the amorphous silicon-containing coating to a temperature greater than 600 degrees Celsius;
wherein the amorphous silicon-containing coating does not crystallize;
wherein a carbon-silicon containing coating is positioned between the amorphous silicon-containing coating and the substrate.

2. The process of claim 1, wherein the temperature of the exposing of the amorphous silicon-containing coating is greater than 650 degrees Celsius.

3. The process of claim 1, wherein the temperature of the exposing of the amorphous silicon-containing coating is greater than 700 degrees Celsius.

4. The process of claim 1, wherein the temperature of the exposing of the amorphous silicon-containing coating is greater than 720 degrees Celsius.

5. The process of claim 1, wherein the temperature of the exposing of the amorphous silicon-containing coating is greater than 750 degrees Celsius.

6. The process of claim 1, wherein the temperature of the exposing of the amorphous silicon-containing coating is greater than 790 degrees Celsius.

7. The process of claim 1, wherein the temperature of the exposing of the amorphous silicon-containing coating is between the 600 degrees Celsius and 800 degrees Celsius.

8. The process of claim 1, wherein the temperature of the exposing of the amorphous silicon-containing coating is between 700 degrees Celsius and 800 degrees Celsius. amorphous silicon-containing coating is between the 750 degrees Celsius and 800 degrees Celsius.

10. (canceled)

11. The process of claim 1, wherein an oxide layer is positioned between the carbon-silicon containing coating and the amorphous silicon-containing layer.

12. The process of claim 1, wherein the substrate is a ferrous-based alloy.

13. The process of claim 1, wherein the substrate is a non-ferrous-based alloy.

14. The process of claim 1, wherein the substrate is a nickel-based alloys.

15. The process of claim 1, wherein the substrate is martensitic stainless steel.

16. The process of claim 1, wherein the substrate is austenitic stainless steel.

17. The process of claim 1, wherein the substrate is a ceramic.

18. The process of claim 1, wherein during, after, or both during and after the exposing of the amorphous silicon-containing coating to the temperature greater than the 600 degrees Celsius, the component is used in a process comprising one or both of:
NOx, SOx, NH3, H2S, mercaptans, hydrocarbons, HCl, volatile organic compounds, Mercury, polycyclic aromatic hydrocarbons, naphtha, petroleum naptha, cylcoalkanes, fuel oils, natural gas, hydrogen, heavy gas oils, ethanolamines, vacuum gas oil, bunker fuels, petroleum distillates, heavy crudes, distillate bottoms, jet fuels, diesel fuels, gasoline, kerosene, saturated hydrocarbons, straight chain alkanes, alkenes, isobutane, ethylene, propylene, ethane, H₂O as steam, HF, H₂SO₄, or combinations thereof; and
a catalytic converter system, a stationary power generation system, a high temperature refining system, a high temperature petrochemical system, a steam reformer, a HF process, a steam cracker, a pilot plant, a combustion engine, combustion chamber, or combinations thereof.

19. A component, comprising:
a substrate; and
an amorphous silicon-containing coating;
wherein the amorphous silicon-containing coating has been exposed to a temperature greater than 600 degrees Celsius and wherein the amorphous silicon-containing coating did not crystallize.

20. A system, comprising a component, the component
a substrate; and
an amorphous silicon-containing coating;
wherein the amorphous silicon-containing coating has been exposed to a temperature greater than 600 degrees Celsius and wherein the amorphous silicon-containing coating did not crystallize.
